(19) United States
(12) Patent Application Publication
(10) Pub. No.: US 2026/0142438 A1
(43) Pub. Date: May 21, 2026

(54) ELECTRO-ABSORPTION MODULATED LASER DIODE

(71) Applicant: ELECTRONICS AND TELECOMMUNICATIONS RESEARCH INSTITUTE, Daejeon (KR)

(72) Inventors: Jun Hwan SHIN, Daejeon (KR); Nam Je KIM, Daejeon (KR); O Kyun KWON, Daejeon (KR); Mi Ran PARK, Daejeon (KR); Seung Chul LEE, Daejeon (KR)

(21) Appl. No.: 19/361,927

(22) Filed: Oct. 17, 2025

(30) Foreign Application Priority Data
Nov. 19, 2024 (KR) 10-2024-0164851

(51) Int. Cl. H01S 5/026; H01S 5/042; H01S 5/34

(52) U.S. Cl. CPC H01S 5/0265; H01S 5/042; H01S 5/34

(57) ABSTRACT

The present invention relates to an electro-absorption modulated laser (EML) diode including a laser diode formed on one side of a substrate, an electro-absorption modulator (EAM) formed on the other side of the substrate, and an anti-parallel (AP) diode integrated with a bias and a radio frequency (RF) feeding line at a front stage of the EAM.

### CROSS-REFERENCE TO RELATED APPLICATION

This application claims priority to and the benefit of Korean Patent Application No. 10-2024-0164851, filed on Nov. 19, 2024, the disclosure of which is incorporated herein by reference in its entirety.

### BACKGROUND

### 1. Field of the Invention

The present invention relates to an electro-absorption modulated laser (EML) diode for improving linearity of an output signal of the EML diode, which is an optical transmission element in an analog radio-over-fiber (ROF) optical link system.

### 2. Discussion of Related Art

In general, unlike electromagnetic waves that electrically transmit signals, messages, or other forms of information, optical communication refers to the transmission of information using optical area electromagnetic waves, such as laser light.

A basic configuration of an analog radio-over-fiber (ROF) optical link for optical communication includes a transmitter that transmits a radio frequency (RF) signal including data through electrical-to-optical (E/O) conversion, and a receiver that detects and receives amplitude information of the optical signal transmitted through an optical fiber through optical-to-electrical (O/E) conversion.

Here, the transmitter includes a laser light source and a modulation device for applying a data signal, and the receiver includes a photodetector for data restoration through envelope detection and a low-noise amplifier for amplifying the received signal.

When the analog ROF optical link is applied to a fronthaul link for mass data and high-speed data transmission, as an RF carrier frequency increases, mass data transmission using a high-level modulation method such as quadrature amplitude modulation (QAM) and multiplexed transmission using a plurality of RF channels through optical subcarrier multiplexing (OSM) represented by orthogonal frequency division modulation (OFDM) are possible in the same band, thereby enabling highly efficient bandwidth operation and minimizing interference between frequency bands.

In addition, since digital signal processing including high-speed digital-to-analog converter (DAC) and analog-to-digital converter (ADC) and frequency up/down conversion processes, a configuration of low-power baseband unit and remote radio head is possible through a simplified system structure with a low-cost, and it is suitable for wideband, low-latency, and real-time wireless communication services.

The related art of the present invention is disclosed in Korean Registered Patent No. 10-0350320 (published on Aug. 28, 2002).

The above-described information disclosed in the technology that forms the background of the present invention is only intended to improve understanding of the background of the present invention, and thus may include information that does not constitute the related art.

### SUMMARY OF THE INVENTION

However, although optical subcarrier multiplexing (OSM)-based analog optical link transmission necessarily requires linear electrical-to-optical (E/O) and optical-to-electrical (O/E) conversion characteristics, noise and spurious components in-band due to optical and electrical nonlinear distortion of components are major factors that limit linearity and transmission performance of the entire system.

Therefore, in order to improve transmission performance of the link, it is important to secure linear response characteristics of optical elements that are main components.

To this end, a method of improving nonlinear modulation characteristics of a bias+radio frequency (RF) signal of an optical modulator that converts an RF signal into an optical signal in a transmitter is essential.

Among intermodulation distortion (IMD) components, which are up- and down-conversion components due to interference between RF signals generated as a result of nonlinear distortion of wideband multi-tone RF signal input, a third-order component third order intermodulation (TOI) corresponding to 2*f1−f2 and 2*f2−f1) is a main component that degrades transmission performance of a radio-over-fiber (ROF) optical link. Since the TOI is positioned in a band adjacent to an input frequency, it is difficult to remove by electrical and optical filtering, and unnecessary spectrum is caused due to interference of the same and adjacent bands, which becomes a factor in degradation of transmission quality of the signal.

Linearization methods of implementing a high-linear analog optical link system include a pre-distortion method based on digital signal processing considering a memory effect and nonlinear characteristics of an optical modulator, an optical method of utilizing different nonlinear response characteristics according to transverse electric (TE)/transverse magnetic (TM) polarization or a wavelength and nonlinear characteristics of a semiconductor optical amplifier, and a method of utilizing a pre-distortion circuit (PDC) positioned in a front stage of the optical modulator and generating the same frequency component with a 180° phase difference from a nonlinear distortion component by the optical modulator.

Among the components, the PDC can be implemented in a relatively simple circuit form without additional optical and electrical function components and modules required for a digital signal processing (DSP)-based or optical method, so the PDC has the advantage of being implemented at low cost and low power without increasing system complexity.

The present invention provides an electro-absorption modulated laser (EML) diode in which an anti-parallel (AP) diode for pre-distortion is integrated with a front stage of an electro-absorption modulator (EAM) in order to improve linearity of an output signal of the EML diode that is an optical transmission element in the analog ROF optical link system.

However, the technical problems to be solved by the present invention are not limited to the above-described problem, and other problems that are not mentioned can be clearly understood by those skilled in the art from the following description of the present invention.

According to an aspect of the present invention, there is provided an EML diode including a laser diode formed on one side of a substrate, an EAM formed on the other side of the substrate, and an AP diode integrated with a bias and an RF feeding line at a front stage of the EAM.

In the present invention, the AP diode may be formed such that a first diode and a second diode have opposite polarities and are positioned in parallel.

In the present invention, the EAM may have a structure in which an n contact layer, an n-type cladding layer, an active layer, a p-type cladding layer, and a p contact layer are stacked.

In the present invention, the AP diode may include a first diode in which the n contact layer, the n-type cladding layer, the active layer, the p-type cladding layer, and the p contact layer are stacked, the n contact layer, the n-type cladding layer, and the p contact layer are shared with the n contact layer, the n-type cladding layer, and the p contact layer of the EAM, and the active layer and the p-type cladding layer are separated from the active layer and the p-type cladding layer of the EAM by the trench-type first blocking layer; and a second diode separated from the first diode and from the active layer and the p-type cladding layer by a trench-type second blocking layer and connected in a reverse direction.

In the present invention, the active layer may be formed with a SCH/MQW/SCH structure.

In the present invention, each of the first blocking layer and the second blocking layer may be formed of a low-k material.

In the present invention, the low-k material may be any one of benzocyclobutene (BCB), SU-8, polystyrene, SUEX, parylene, polyimide poly methyl methacrylate (PMMA).

In the present invention, each of the first blocking layer and the second blocking layer may be formed with an air-bridge structure.

In the present invention, anode electrodes of the first diode and the second diode may have a shape of fingers, may be positioned in parallel, and may be formed with the same or different areas.

In the present invention, the AP diode may include a first diode in which the n contact layer, the n-type cladding layer, and the p contact layer are stacked, the n contact layer, the n-type cladding layer, and the p contact layer are shared with the n contact layer, the n-type cladding layer, and the p contact layer of the EAM, and the active layer and the p-type cladding layer of the EAM are separated by a trench-type first blocking layer, and the n-type cladding layer and the p contact layer form a junction; and a second diode separated from the first diode by a trench-type second blocking layer and connected in a reverse direction.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a schematic diagram illustrating an electro-absorption modulated laser (EML) diode according to one embodiment of the present invention;

FIG. 2 is a cross-sectional view illustrating an anti-parallel (AP) diode integrated with an electro-absorption modulator (EAM) in the EML diode according to one embodiment of the present invention;

FIG. 3 is a plan view illustrating the AP diode in the EML diode according to one embodiment of the present invention;

FIG. 4 is a cross-sectional view illustrating the AP diode in the EML diode according to one embodiment of the present invention;

FIG. 5 is a graph showing current-voltage characteristics of the AP diode in the EML diode according to one embodiment of the present invention;

FIG. 6 is an equivalent circuit diagram illustrating the EAM including the AP diode in the EML diode according to one embodiment of the present invention;

FIG. 7 is a graph showing an output spectrum of the EAM in the EML diode according to one embodiment of the present invention; and

FIG. 8 is a structural block diagram in which the EML diode according to one embodiment of the present invention is expressed as a transfer function.

### DETAILED DESCRIPTION OF EXEMPLARY EMBODIMENTS

Hereinafter, an electro-absorption modulated laser (EML) diode according to the present invention will be described with reference to the accompanying drawings.

In this process, thicknesses of lines, sizes of constituent elements, or the like illustrated in the drawings, may be exaggerated for clarity and convenience of description. In addition, the terms described below are defined in consideration of the functions of the present invention, and these terms may be varied according to the intent or custom of a user or an operator. Therefore, these terms should be defined on the basis of the contents throughout the present application.

Hereinafter, embodiments of the present invention will be fully described in detail, which is suitable for easy implementation by those skilled in the art to which the present invention pertains with reference to the accompanying drawings. However, the present invention may be implemented in various different forms, and thus it is not limited to embodiments to be described herein. In the drawings, some portions not related to the description will be omitted in order to clearly describe the present invention, and similar reference numerals are given to similar components throughout this disclosure.

Throughout the present specification, when a part is referred to as “including” a component, this means that the part can include other elements, rather than excluding any other components unless specifically stated otherwise.

Implementations described herein may also be implemented by, for example, a method or process, an apparatus, a software program, a data stream, or a signal. Even when only discussed in the context in a single form of implementation (e.g., discussed only as a method), the implementation of features discussed may also be implemented in other forms (e.g., an apparatus or program). The apparatus may be implemented in suitable hardware, software, and firmware. The method may be implemented in an apparatus such as a processor, which is generally referred to as a processing device including, for example, a computer, a microprocessor, an integrated circuit, or a programmable logic device.

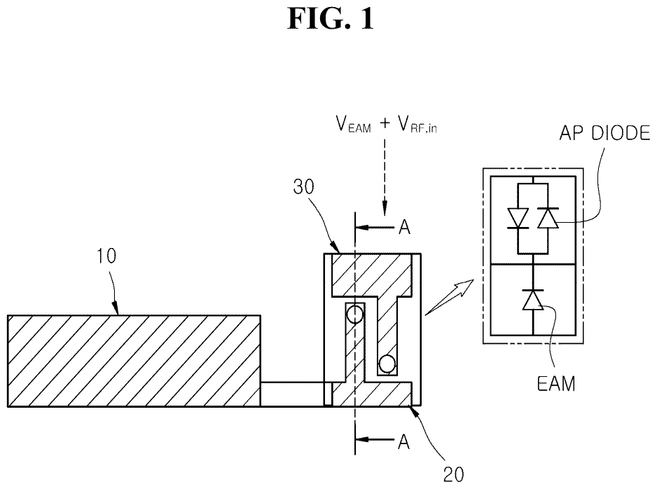

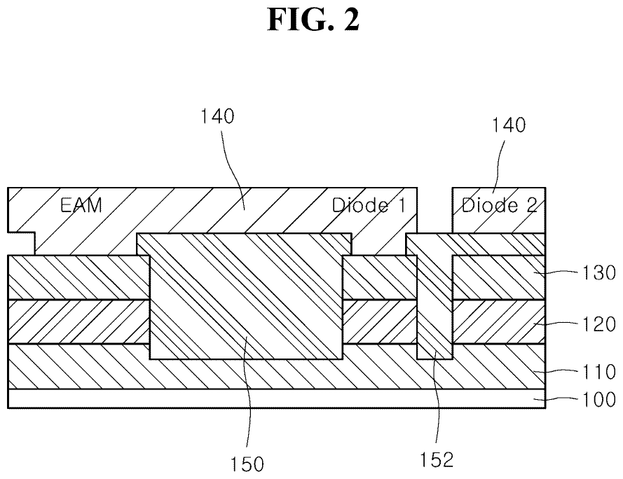

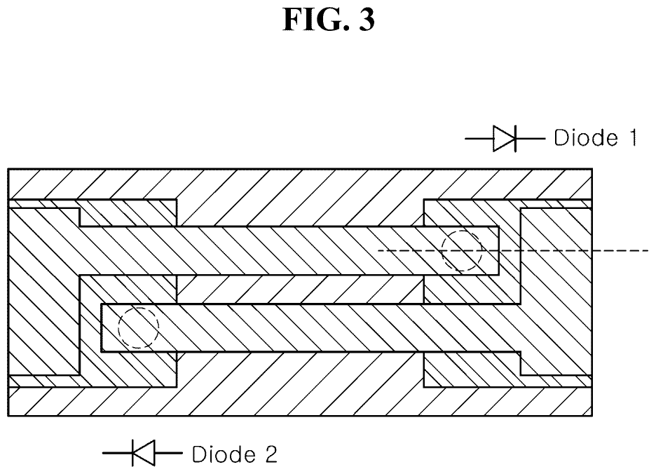

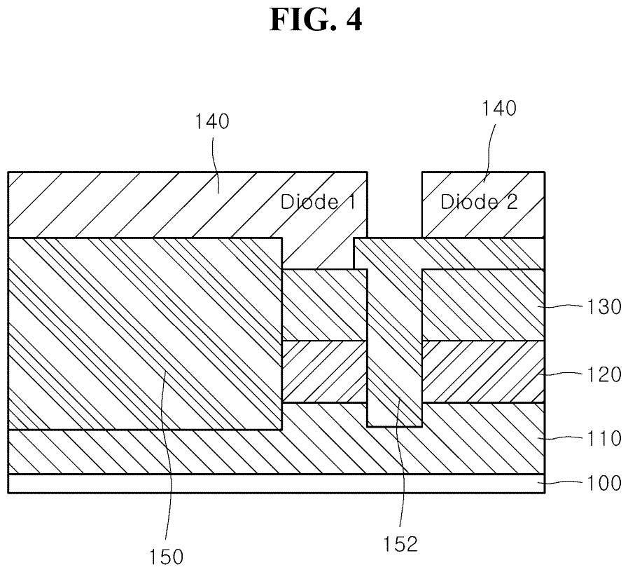

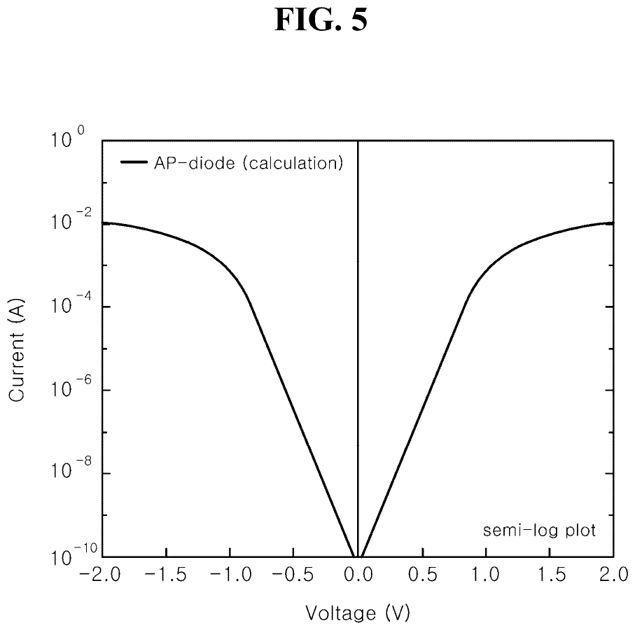

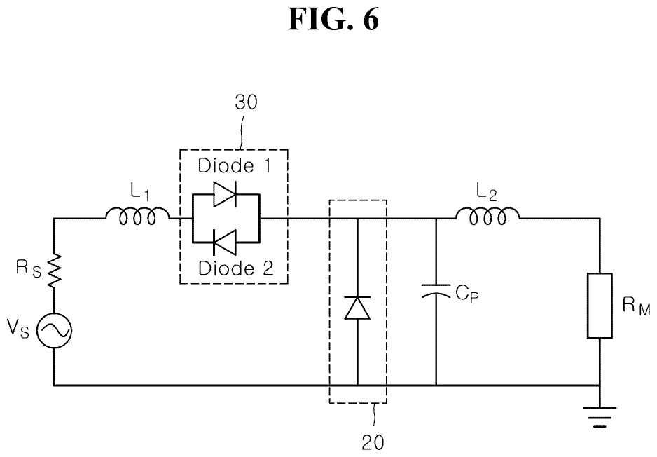

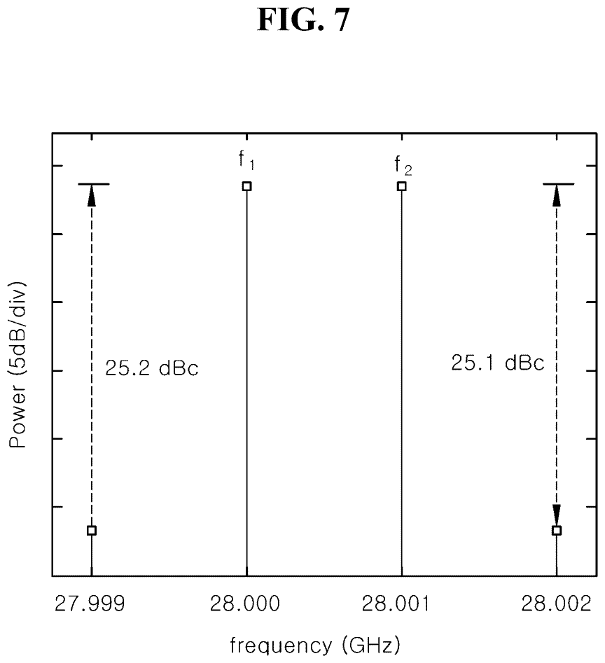

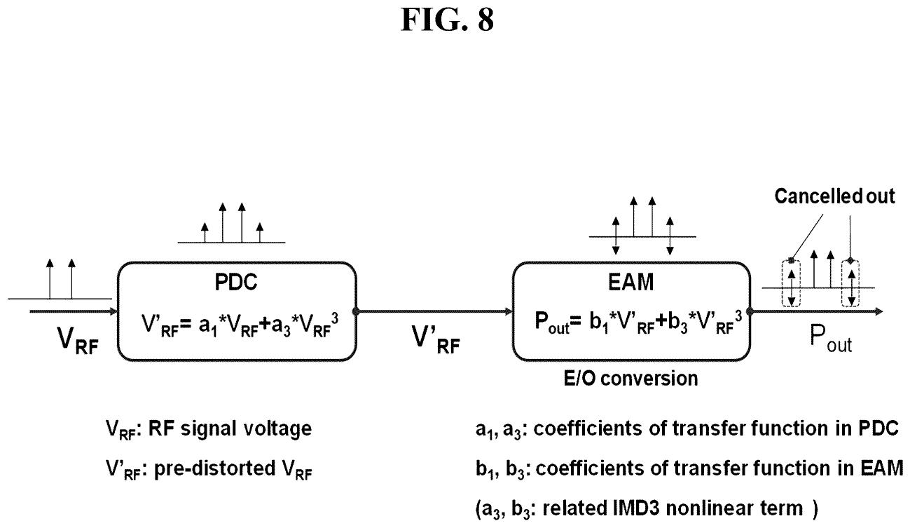

FIG. 1 is a schematic diagram illustrating an EML diode according to one embodiment of the present invention, FIG. 2 is a cross-sectional view illustrating an anti-parallel (AP) diode integrated with an electro-absorption modulator (EAM) in the EML diode according to one embodiment of the present invention, FIG. 3 is a plan view illustrating the AP diode in the EML diode according to one embodiment of the present invention, FIG. 4 is a cross-sectional view illustrating the AP diode in the EML diode according to one embodiment of the present invention, FIG. 5 is a graph showing current-voltage characteristics of the AP diode in the EML diode according to one embodiment of the present invention, FIG. 6 is an equivalent circuit diagram illustrating the EAM including the AP diode in the EML diode according to one embodiment of the present invention, FIG. 7 is a graph showing an output spectrum of the EAM in the EML diode according to one embodiment of the present invention, and FIG. 8 is a structural block diagram in which the EML diode according to one embodiment of the present invention is expressed as a transfer function.

As shown in FIG. 1, an EML diode according to one embodiment of the present invention may include a laser diode 10, an EAM 20, and an AP diode 30.

The laser diode 10 is formed on one side of a substrate and generates light.

The EAM 20 may be formed on the other side of the substrate and modulate the light generated from the laser diode 10 to output an optical signal.

In this case, a distributed feedback (DFB) laser diode is used as the laser diode 10, and the laser diode 10 and the EAM 20 may be formed by sharing an active layer of a buried heterostructure (BH) type formed with a multiple quantum well (MQW) structure.

The AP diode 30 may be integrated with a bias and a radio frequency (RF) feeding line at a front stage of the EAM 20.

Here, in the AP diode 30, a first diode and a second diode may have opposite polarities and may be positioned in parallel.

In this case, an electrode width of the AP diode 30 may be formed to be less than or equal to an electrode length of the EAM 20 so that a cutoff frequency is not lowered due to an increase in capacitance of the EAM 20.

In general, when the electrode length of the EAM 20 for high-speed data transmission is formed in the range of 100 μm to 200 μm and applied in a 28 GHz band, which is a carrier frequency, the EAM 20 may be integrated with a size less than or equal to 1/10 of a wavelength of a transmission signal so that matching is possible through adjustment of a resistor, which is a lumped passive element, and a bonding wire in the existing chip on carrier (CoC) without a separate impedance matching circuit while minimizing an increase in chip area and optimization of a generated signal for distortion compensation with a minimum error vector magnitude (EVM) within an optical link is possible, thereby reducing design complexity.

FIG. 2 is a cross-sectional view illustrating the AP diode 30 integrated with the EAM of FIG. 1, and as shown in a A-A cross-sectional view, the EAM 20 may be formed with a structure in which an n contact layer 100, an n-type cladding layer 110, an active layer 120, a p-type cladding layer 130, and a p contact layer 140 are stacked.

In addition, a first diode Diode1 constituting the AP diode 30 may be formed such that the n contact layer 100, the n-type cladding layer 110, the active layer 120, the p-type cladding layer 130, and the p contact layer 140 are stacked, and the n contact layer 100, the n-type cladding layer 110, and the p contact layer 140 may be formed such that the n contact layer 100, the n-type cladding layer 110, and the p contact layer 140 of the EAM 20 are shared, and the active layer 120 and the p-type cladding layer 130 may be formed to be separated from the active layer 120, the p-type cladding layer 130, and a trench-type first blocking layer 150 of the EAM 20.

In addition, in a second diode Diode2, the active layer 120 and the p-type cladding layer 130 may be separated from the first diode Diode1 by the trench-type second blocking layer 152 and connected in a reverse direction.

In this case, the active layer 120 may be formed with a multilayer quantum well SCH/MQW/SCH structure.

In addition, each of the first blocking layer 150 and the second blocking layer 152 may be made of a low-k material.

Here, the low-k material may be any one of benzocyclobutene (BCB), SU-8, polystyrene, SUEX, parylene, polyimide, and poly methyl methacrylate (PMMA).

Meanwhile, each of the first blocking layer 150 and the second blocking layer 152 may be formed with an air-bridge structure.

In this way, the EAM 20 and the first diode Diode1 of the AP diode 30 may be electrically separated by the first blocking layer 150 and the second blocking layer 152, and the first diode Diode1 and the second diode Diode2 may also be electrically separated from each other.

In addition, as shown in FIG. 3, anode electrodes of the first diode Diode1 and the second diode Diode2 constituting the AP diode 30 may have a finger shape, may be positioned in parallel, and may be formed with the same area or different areas.

Here, a bandwidth of the AP diode 30 may secure a 3 dB bandwidth or more of the EAM 20 satisfying Equation 1 in order to minimize degradation of modulation performance of the EAM 20 for the input RF signal.

$${f}_{3 dB , AP - SBD} = \frac{1}{2 π {R}_{s} {C}_{j}} \geq {f}_{3 dB , EAM} \qquad [ Equation 1 ]$$

Therefore, a junction capacitance Cj and a series resistance (RS) component may be controlled by adjusting an area of the anode electrode so as to satisfy Equation 1.

That is, when the anode junction area is formed, in consideration of an optimal operating bias voltage of the EAM 20, the areas of the first diode Diode1 and the second diode Diode2 may be formed different from each other to have a current-voltage characteristic curve that is horizontally shifted shape in an x-axis direction rather than a y-axis symmetrical shape as shown in FIG. 5.

Here, FIG. 5 is a diagram illustrating the current-voltage characteristics when the anode junction areas of the first diode Diode1 and the second diode Diode2 of AP diode 30 are the same, by reflecting properties of an epitaxial structure of EAM 20.

However, when Equation 1 is not satisfied, the p-type cladding layer 130 and the active layer 120 of the first diode Diode1 and the second diode Diode2 may be removed through an etching process to manufacture a zero-bias Schottky barrier diode (SBD) structure in which the p contact layer 140 and the n-type cladding layer 110 form a junction.

In addition, a protective layer may be formed with a polymer-type dielectric that has a low-K so as to secure broadband frequency characteristics with a high cutoff frequency and is formable with a thickness of several hundred nm to several μm or more to secure surface flatness and reduce parasitic capacitance. In this case, benzocyclobutene (BCB) may be used as a material of the protective layer, and when a bandwidth of 100 GHz or more is required, polymers such as SU-8, polystyrene, SUEX, parylene, polyimide, and PMMA may be included.

FIG. 6 is an equivalent circuit including the EAM and the AP diode, and L₁ and L₂ are bonding wires, C_{P} is a pad capacitance, R_{M} is a matching load, and V_{S} is an RF signal source.

In this way, in order to quantitatively analyze a nonlinear response to the RF signal of the EAM 20 in which the AP diode is integrated, as a result of a harmonic-balance (HB) method of analyzing a nonlinear system for multi-tone signals with the same output and phase at a bias voltage (VEAM=−1.5 V) of a linear operating region of the EAM 20 and analyzing harmonic generation and intermodulation distortion of a circuit, as shown in FIG. 7, it can be confirmed that an input fundamental frequency (f1=28 GHz and f2=28.001 GHz) and a third-order intermodulation (TOI) are expressed in an output spectrum, and third-order inter-modulation distortion (IMD3) (lower: 25.2 dBc and upper: 25.1 dBc) characteristics defined as a difference in magnitude of a fundamental frequency and a TOI component is obtained.

This may increase the IMD3 of the output spectrum of the EAM 20 by causing a TOI component of the RF signal pre-distorted by the integrated AP diode 30 to offset the TOI component generated by the EAM 20.

As shown in FIG. 8, when a pre-distortion circuit (PDC) is formed at a front stage of an EAM in the EML diode to satisfy the condition of Equation 2, an IMD3 having a 180° phase difference and the same amplitude as the IMD3 component due to the nonlinear characteristics of the laser light source may be generated, thereby improving nonlinear characteristics of the light source through destructive interference.

When the PDC is implemented using the nonlinear current-voltage characteristics of a diode to perform such a pre-distortion function, pre-distortion IMD may be generated by a nonlinear current-voltage for a wideband RF input signal over the DC-tens of GHz band, and when an AP structure is applied, an even-order IMD component generated from the RF signal may be removed within the device by a push-pull operation method so that a compensation TOI signal may be efficiently generated. In addition, a low-power operation and miniaturization are possible so that it is advantageous for integration into the existing semiconductor laser diode chip.

$${a}_{1} * {V}_{RF} + {a}_{3} * {V}_{RF}^{3} = {V}_{RF}^{′} \qquad [ Equation 2 ]$$

$${V}_{out} = {b}_{1} * {V}_{RF}^{′} + {b}_{3} * {V}_{RF}^{′ 3} = {\underbrace{{V}_{RF}^{3} ( {b}_{1} * {a}_{3} + {b}_{3} * {a}_{1}^{3} )}}_{0} + … +$$

$$∴ \frac{{a}_{1}^{3}}{{a}_{3}} = - \frac{{b}_{1}}{{b}_{3}} \qquad [ Equation 3 ]$$

As in Equation 2, an input-output transfer function representing linear and nonlinear characteristics of an output signal for the input signal is expressed in the form of a polynomial that describes both the linear and nonlinear characteristics, and in order to remove a third-order nonlinear component due to distortion, the input-output transfer function may be implemented using the nonlinear characteristics of the diode to satisfy Equation 3, and the linearity of the light source may be improved by integrating the diode having a driving current and series resistors that satisfy Equation 3.

As described above, according to the EML diode according to the embodiment of the present invention, in order to improve the linearity of the output signal of the EML diode that is an optical transmission element in an analog ROF optical link system, an AP diode for pre-distortion is integrated with the front stage of the EAM so that integration is possible without increasing the degree of integration and complexity of the element process compared to the conventional configuration, and there is the advantage that no separate power supply is required because an active element is not used, and the linearity of the output signal of the EML diode is improved and thus distortion of the optical signal may be reduced when applied to the optical link, thereby contributing to an increase in transmission distance and an improvement in EVM.

According to one aspect of the present invention, in order to improve the linearity of an output signal of an EML diode that is an optical transmission element in an analog radio-over-fiber (ROF) optical link system, an AP diode for pre-distortion is integrated with a front stage of an EAM, thereby enabling integration without increasing a degree of integration and complexity of an element process when compared to the conventional configuration, and there is an advantage that no separate power supply is required because no active element is used.

In addition, by improving the linearity of the output signal of the EML diode, the distortion of the optical signal can be reduced when applied to an optical link to contribute to an increase in transmission distance and improvement of EVM.

Effects of the present invention are not limited to those described above, and other effects that are not specifically mentioned herein will be clearly understood by those skilled in the art from the description of the present invention below.

While the present disclosure has been described with reference to exemplary embodiments shown in the drawings, these are merely illustrative, and those skilled in the art to which the present invention pertains will understood that various modifications and equivalent other embodiments can be implemented within the spirit and scope of the present invention.

Therefore, the technical scope of the present invention should be defined by the appended claims.

What is claimed is:

1. An electro-absorption modulated laser (EML) diode comprising:
a laser diode formed on one side of a substrate;
an electro-absorption modulator (EAM) formed on the other side of the substrate; and
an anti-parallel (AP) diode integrated with a bias and a radio frequency (RF) feeding line at a front stage of the EAM.

2. The EML diode of claim 1, wherein the AP diode is formed such that a first diode and a second diode have opposite polarities and are positioned in parallel.

3. The EML diode of claim 1, wherein the EAM has a structure in which an n contact layer, an n-type cladding layer, an active layer, a p-type cladding layer, and a p contact layer are stacked.

4. The EML diode of claim 3, wherein the AP diode includes:
a first diode in which the n contact layer, the n-type cladding layer, the active layer, the p-type cladding layer, and the p contact layer are stacked, the n contact layer, the n-type cladding layer, and the p contact layer are shared with the n contact layer, the n-type cladding layer, and the p contact layer of the EAM, and the active layer and the p-type cladding layer are separated from the active layer and the p-type cladding layer of the EAM by the trench-type first blocking layer; and
a second diode separated from the first diode and from the active layer and the p-type cladding layer by a trench-type second blocking layer and connected in a reverse direction.

5. The EML diode of claim 4, wherein the active layer is formed with a SCH/MQW/SCH structure.

6. The EML diode of claim 4, wherein each of the first blocking layer and the second blocking layer is formed of a low-k material.

7. The EML diode of claim 6, wherein the low-k material includes any one of benzocyclobutene (BCB), SU-8, polystyrene, SUEX, parylene, polyimide, and poly methyl methacrylate (PMMA).

8. The EML diode of claim 4, wherein each of the first blocking layer and the second blocking layer is formed with an air-bridge structure.

9. The EML diode of claim 4, wherein anode electrodes of the first diode and the second diode have in a shape of fingers, are positioned in parallel, and are formed with the same or different areas.

10. The EML diode of claim 3, wherein the AP diode includes:
a first diode in which the n contact layer, the n-type cladding layer, and the p contact layer are stacked, the n contact layer, the n-type cladding layer, and the p contact layer are shared with the n contact layer, the n-type cladding layer, and the p contact layer of the EAM, and the active layer and the p-type cladding layer of the EAM are separated by a trench-type first blocking layer, and the n-type cladding layer and the p contact layer form a junction; and
a second diode separated from the first diode by a trench-type second blocking layer and connected in a reverse direction.
